(19) United States
(12) Patent Application Publication
(10) Pub. No.: US 2024/0321841 A1
(43) Pub. Date: Sep. 26, 2024

(54) SEMICONDUCTOR PACKAGE

(71) Applicant: Samsung Electronics Co., Ltd., Suwon-si (KR)

(72) Inventors: Hwanjoo PARK, Suwon-si (KR); Jaechoon KIM, Suwon-si (KR); Sunggu KANG, Suwon-si (KR); Taehwan KIM, Suwon-si (KR)

(73) Assignee: Samsung Electronics Co., Ltd., Suwon-si (KR)

(21) Appl. No.: 18/609,255

(22) Filed: Mar. 19, 2024

(30) Foreign Application Priority Data
Mar. 24, 2023 (KR) 10-2023-0039023
May 22, 2023 (KR) 10-2023-0065884

(51) Int. Cl. H01L 25/10; H01L 23/00; H01L 23/31; H01L 23/373; H01L 23/498; H01L 23/538; H01L 25/065

(52) U.S. Cl. CPC H01L 25/105; H01L 23/3128; H01L 23/3736; H01L 23/49816; H01L 23/5383; H01L 24/16; H01L 24/32; H01L 24/73; H01L 25/0657; H01L 2224/16227; H01L 2224/32225; H01L 2224/73204; H01L 2225/1094

(57) ABSTRACT

The disclosure provides a semiconductor package including a first wiring structure including a first wiring, a first semiconductor chip on the first wiring structure, a molding member surrounding the first semiconductor chip, a second wiring structure on an upper surface of the molding member and including a second wiring and a heat conductive metal, a second semiconductor chip on an upper surface of the second wiring structure, a plurality of first bumps between the second wiring structure and the second semiconductor chip, an underfill layer covering the plurality of first bumps, and a first thermal interface material (TIM) on an upper surface of the heat conductive metal, the heat conductive metal not overlapping the plurality of first bumps in the vertical direction.

### CROSS-REFERENCE TO RELATED APPLICATION

This application is based on and claims priority under 35 U.S.C. § 119 to Korean Patent Application Nos. 10-2023-0039023, filed on Mar. 24, 2023, and 10-2023-0065884, filed on May 22, 2023 in the Korean Intellectual Property Office, the disclosures of which are incorporated by reference herein in their entireties.

### BACKGROUND

The disclosure relates to semiconductor packages, and more particularly, to semiconductor packages with improved thermal characteristics.

Recently, the electronic product market has experienced a dramatic increase in the demand for portable devices, and as a result, miniaturization and lightweighting of electronic components mounted on these electronic products are continuously required. In order to reduce the size and weight of electronic components, a semiconductor package mounted thereon is required to have a reduced volume and also be capable of processing large amounts of data. With the miniaturization and weight reduction of semiconductor packages, dissipation of heat generated inside a semiconductor package has become an important problem.

### SUMMARY

The invention concepts provide semiconductor packages having improved thermal characteristics.

In addition, the problems to be solved by the technical ideas of the disclosure are not limited to the above-mentioned problems, and other problems may be clearly understood by those skilled in the art from the description below.

In order to solve the technical problems, the disclosure provides semiconductor packages as follows.

According to some aspects of the disclosure, there is provided a semiconductor package including a first wiring structure including a first wiring configured to transmit electrical signals, a first semiconductor chip on the first wiring structure, a molding member surrounding the first semiconductor chip, a second wiring structure including a second wiring and a heat conductive metal, the second wiring structure on an upper surface of the molding member, the second wiring is configured to transmit an electrical signal, and the heat conductive metal is not electrically connected to the second wiring, a second semiconductor chip on an upper surface of the second wiring structure, a plurality of first bumps between the second wiring structure and the second semiconductor chip and electrically connecting the second wiring to the second semiconductor chip, an underfill layer covering the plurality of first bumps, and a first thermal interface material (TIM) formed on an upper surface of the heat conductive metal, the upper surface of the heat conductive metal exposed in a vertical direction from the second wiring structure, and the heat conductive metal not overlapping the plurality of first bumps in the vertical direction.

According to some aspects of the disclosure, there is provided a semiconductor package including a first wiring structure including a first wiring configured to transmit electrical signals, a first semiconductor chip on the first wiring structure, a molding member surrounding the first semiconductor chip, a second wiring structure including a second wire configured to transmit an electrical signal, a heat conductive metal not electrically connected to the second wire, and a heat conductive via pattern contacting an upper surface of the first semiconductor chip and extending in a vertical direction, the second wiring structure on an upper surface of the molding member, a second semiconductor chip on an upper surface of the second wiring structure, a plurality of first bumps between the second wiring structure and the second semiconductor chip and electrically connecting the second wiring to the second semiconductor chip, an underfill layer covering the plurality of first bumps, and a first TIM on an upper surface of the heat conductive metal, the upper surface of the heat conductive metal exposed in a vertical direction from the second wiring structure, the upper surface of the molding member on a same plane with an upper surface of the second semiconductor chip, and the heat conductive metal not overlapping the plurality of first bumps in the vertical direction.

According to some aspects of the disclosure, there is provided a semiconductor package comprising: a first wiring structure including a first wiring configured to transmit an electrical signal, and a first wiring insulating layer covering the first wiring, a first semiconductor chip on the first wiring structure, a molding member surrounding the first semiconductor chip, a second wiring structure including a second wire configured to transmit an electrical signal, a heat conductive metal not electrically connected to the second wire, a heat conductive via pattern contacting an upper surface of the first semiconductor chip and extending in a vertical direction, and a second wire insulating layer covering the second wire, the heat conductive metal, and the heat conductive via pattern, the second wiring structure on an upper surface of the molding member, a conductive pillar vertically penetrating the molding member and electrically connecting the first wiring to the second wire, a second semiconductor chip on an upper surface of the second wiring structure, a plurality of first bumps positioned between the second wiring structure and the second semiconductor chip and electrically connecting the second wiring to the second semiconductor chip, an underfill layer covering the plurality of first bumps, and a first TIM formed on an upper surface of the heat conductive metal, the plurality of first bumps surround a first area corresponding to a central portion of the underfill layer, the upper surface of the heat conductive metal is exposed in a vertical direction from the second wiring structure, the upper surface of the molding member is on a same plane with an upper surface of the second semiconductor chip, the second wiring insulating layer includes at least one of PID and photosensitive polyimide, and the heat conductive metal not overlapping the plurality of first bumps in the vertical direction.

### BRIEF DESCRIPTION OF THE DRAWINGS

Example embodiments of the disclosure will be more clearly understood from the following detailed description taken in conjunction with the accompanying drawings in which:

FIG. 1 is a cross-sectional view illustrating a semiconductor package according to some example embodiments;

FIG. 2 is a cross-sectional view of the semiconductor package of FIG. 1 taken along line X1-X1′;

FIG. 3 is a cross-sectional view illustrating a semiconductor package according to some example embodiments;

FIG. 4 is a cross-sectional view of the semiconductor package of FIG. 3 taken along line X2-X2′;

FIG. 5 is a cross-sectional view illustrating a semiconductor package according to some example embodiments;

FIG. 6 is an enlarged view of portion AA of the semiconductor package of FIG. 5;

FIG. 7 is a cross-sectional view illustrating a semiconductor package according to some example embodiments;

FIG. 8 is a cross-sectional view illustrating a semiconductor package according to some example embodiments; and

FIG. 9 is a cross-sectional view illustrating a semiconductor package according to some example embodiments.

### DETAILED DESCRIPTION

Hereinafter, example embodiments of the disclosure are described in detail with reference to the accompanying drawings. The same reference numerals are used for the same components in the drawings, and descriptions already given for the components are omitted.

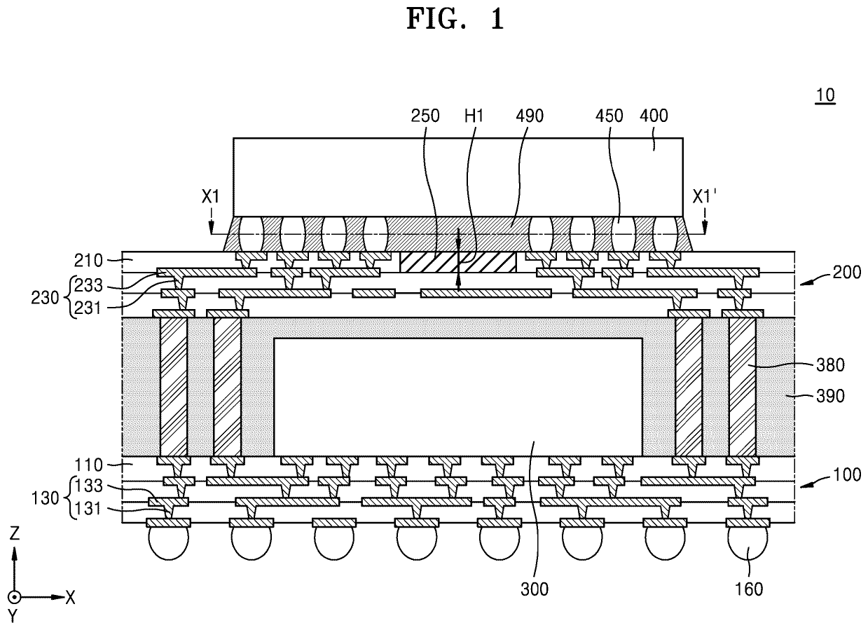

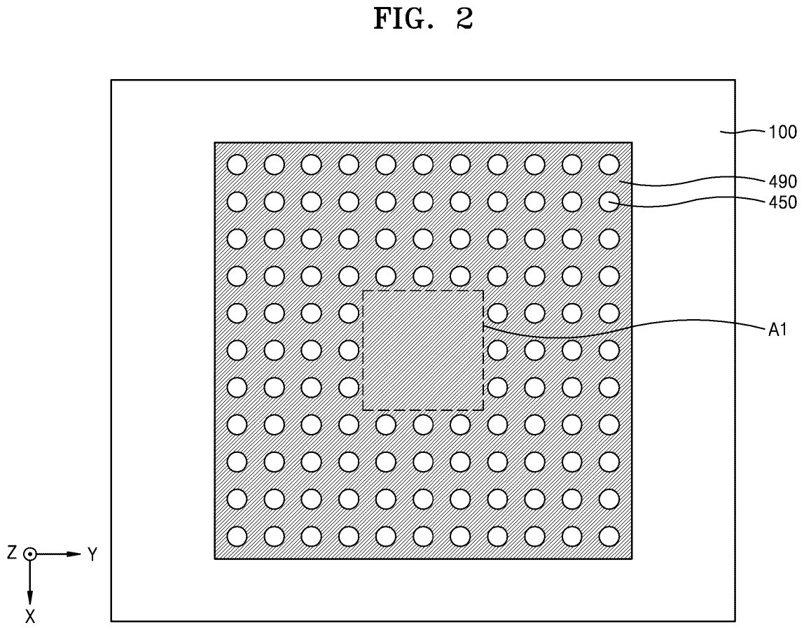

FIG. 1 is a cross-sectional view illustrating a semiconductor package according to some example embodiments. FIG. 2 is a cross-sectional view of the semiconductor package of FIG. 1 taken along line X1-X1′.

Referring to FIGS. 1 and 2, a semiconductor package 10 according to the technical concept of the disclosure may include a first wiring structure 100, a first semiconductor chip 300, a second wiring structure 200, and a second semiconductor chip 400.

The first wiring structure 100 may include upper and lower surfaces opposite to each other, and at least one of the upper and lower surfaces may be flat. The first wiring structure 100 may be disposed below the first semiconductor chip 300 and electrically connect the first semiconductor chip 300 to an external connection bump 160 to each other. The first wiring structure 100 may include a first wiring insulating layer 110 and a first wiring 130.

The first wiring insulating layer 110 may be provided as a plurality of layers stacked in one direction, and the first wiring 130 may include a plurality of patterns formed in the stacked insulating layers.

In the drawings below, a direction in which the plurality of insulating layers are stacked may be a Z-axis direction, and an X-axis direction and a Y-axis direction may be directions perpendicular to each other in a plane having the Z-axis direction as a normal vector. That is, the X-axis direction and the Y-axis direction may represent directions parallel to the upper or lower surface of the first wiring structure 100, and the X-axis direction and the Y-axis direction may be directions perpendicular to each other. The Z-axis direction may indicate a direction perpendicular to the upper or lower surface of the first wiring structure 100, that is, a direction perpendicular to an X-Y plane. Also, in the following drawings, the first horizontal direction, the second horizontal direction, and the vertical direction may be understood as follows. The first horizontal direction may be the X-axis direction, the second horizontal direction may be the Y-axis direction, and the vertical direction may be the Z-axis direction.

The first wiring 130 may be electrically connected to a conductive pillar 380 and the first semiconductor chip 300. The first wiring 130 may include a first wiring via 131 and a first wiring line 133. The first wiring line 133 may have a shape extending in the first horizontal direction X within the first wiring insulating layer 110. According to some example embodiments, the first wiring line 133 may be provided on each of the plurality of first wiring insulating layers 110 stacked in the vertical direction Z. A first wiring via 131 may extend in the vertical direction Z and may penetrate the first wiring insulating layer 110 in the vertical direction Z. The first wiring via 131 may electrically connect the first wiring lines 133 respectively formed in the first wiring insulating layers 110 that are different from each other.

In some example embodiments, the first wiring via 131 may have a tapered shape extending from a lower side to an upper side with a wider horizontal width. For example, the horizontal width of the first wiring via 131 may increase as the first wiring via 131 approaches the first semiconductor chip 300. In some example embodiments, the first wiring via 131 may have a tapered shape in which a horizontal width increases as the level in the vertical direction Z decreases.

In some example embodiments, the first wiring structure 100 may be a redistribution structure manufactured through a redistribution process. In this case, the first wiring insulating layer 110 may include, for example, photo imageable dielectric (PID) or photosensitive polyimide (PSPI), and the first wiring 130 may include, for example, copper (Cu), aluminum (Al), tungsten (W), titanium (Ti), tantalum (Ta), indium (In), molybdenum (Mo), manganese (Mn), It may be a metal or an alloy of metals such as cobalt (Co), tin (Sn), nickel (Ni), magnesium (Mg), rhenium (Rc), beryllium (Be), gallium (Ga), ruthenium (Ru), etc., but the disclosure is not limited thereto. In some example embodiments, the first wiring 130 may be formed by depositing a metal or metal alloy on a seed layer including copper, titanium, titanium nitride, or titanium tungsten. According to some example embodiments, the first wiring line 133 may be integrally formed with the first wiring via 131.

When the first wiring structure 100 is a redistribution structure manufactured through a redistribution process, the first wiring 130 may be a redistribution pattern, and the first wiring insulation layer 110 may be a redistribution insulation layer.

In some example embodiments, the first wiring structure 100 may be a printed circuit board (PCB). In this case, the first wiring insulating layer 110 may be made of at least one material selected from phenol resin, epoxy resin, and polyimide. The first wiring insulating layer 110 may include, for example, at least one material selected from frame retardant 4 (FR-4), tetrafunctional epoxy, polyphenylene ether, epoxy/polyphenylene oxide, bismaleimide triazine (BT), thermount, cyanate ester, polyimide, and liquid crystal polymer In addition, the first wiring 130 may be made of copper, nickel, stainless steel, or beryllium copper.

The external connection bump 160 may be positioned below the first wiring structure 100. The external connection bump 160 may be electrically connected to an external device, for example, a motherboard. The external connection bump 160 may be electrically connected to the first wiring 130. The external connection bumps 160 may transfer electrical signals received from the first semiconductor chip 300 and the second semiconductor chip 400 through the first wiring 130 to external device. The first wiring 130 may be electrically connected to an external device through an external connection bump 160. The external connection bump 160 may include at least one of a conductive material, for example, solder, tin (Sn), silver (Ag), copper (Cu), and aluminum (Al).

The first semiconductor chip 300 may be mounted on the upper surface of the first wiring structure 100. The first semiconductor chip 300 may be electrically connected to the first wiring 130. According to some example embodiments, the first semiconductor chip 300 may be mounted on the first wiring structure 100 in a flip chip method.

The first semiconductor chip 300 may include a memory chip or a logic chip. The memory chip may be, for example, a volatile memory chip such as dynamic random access memory (DRAM) or static random access memory (SRAM), or may be a non-volatile memory chip such as phase-change random access memory (PRAM), magnetoresistive random access memory (MRAM), ferroelectric random access memory (FeRAM), or resistive random access memory (RRAM). The logic chip may be, for example, a microprocessor such as a central processing unit (CPU), a graphics processing unit (GPU), or an application processor (AP), an analog device, or a digital signal.

A molding member 390 may be formed to surround the first semiconductor chip 300 on the upper surface of the first wiring structure 100. In some example embodiments, the molding member 390 may cover the side surface and top surface of the first semiconductor chip 300.

The molding member 390 may be formed from a thermosetting resin such as an epoxy resin, a thermoplastic resin such as polyimide, or a resin including a reinforcing material such as an inorganic filler therein, in detail Ajinomoto build-up film (ABF), FR-4, BT, or the like, but is not limited thereto, and the molding member 390 may be formed of a molding material such as epoxy mold compound (EMC) or a photosensitive material such as photoimagable encapsulant (PIE). In some example embodiments, a portion of the molding member 390 may be made of an insulating material such as a silicon oxide layer, a silicon nitride layer, or a silicon oxynitride layer.

The conductive pillar 380 may be positioned horizontally apart from the first semiconductor chip 300 on the top surface of the first wiring structure 100. According to some example embodiments, a plurality of conductive pillars 380 may be provided. The plurality of conductive pillars 380 may be spaced apart from each other by a distance (for example, a predetermined distance or a desired distance) in a horizontal direction. The conductive pillar 380 may have a shape extending in the vertical direction Z and may penetrate the molding member 390 in the vertical direction Z.

The conductive pillar 380 may electrically connect the second wiring structure 200 and the first wiring structure 100 to each other. That is, the conductive pillar 380 may be a vertical connection conductor for electrically connecting the first wiring structure 100 and the second wiring structure 200 to each other.

The upper surface of the conductive pillar 380 may be on the same plane as the upper surface of the molding member 390. In some example embodiments, the upper surface of the first semiconductor chip 300 may have a level in the vertical direction Z lower than that of the upper surface of the molding member 390.

The second wiring structure 200 may be disposed on an upper surface of the molding member 390. The second wiring structure 200 may include upper and lower surfaces opposite to each other, and at least one of the upper and lower surfaces may be flat. The second wiring structure 200 may electrically connect the conductive pillar 380 and the second semiconductor chip 400 to each other. The second wiring structure 200 may include a second wiring 230, a second wiring insulating layer 210, and a heat conductive metal 250. The second wiring structure 200 may electrically connect the conductive pillar 380 and the second semiconductor chip 400 to each other through the second wiring 230. The second wiring insulating layer 210 may be provided as a plurality of layers stacked in the vertical direction Z. The second wiring 230 may include a second wiring via 231 and a second wiring line 233.

Because the second wiring 230 and the second wiring insulating layer 210 are substantially the same as or similar to the above-described first wiring 130 and the first wiring insulating layer 110, the already given descriptions thereof are omitted.

The heat conductive metal 250 may be formed in the second wiring insulating layer 210 stacked on top of the second wiring insulating layers 210. The uppermost second wiring insulating layer 210 may be formed to cover the side surface of the heat conductive metal 250. The uppermost second wiring insulating layer 210 may not cover the upper surface of the heat conductive metal 250. That is, the heat conductive metal 250 may be exposed upward in the vertical direction Z from the second wiring insulating layer 210. A top surface of the heat conductive metal 250 may be on the same plane as an upper surface of the uppermost second wiring insulating layer 210. An upper surface of the heat conductive metal 250 may contact a lower surface of an underfill layer 490.

According to some example embodiments, the heat conductive metal 250 may include the same metal as the second wiring 230. The heat conductive metal 250 may include, for example, a metal such as copper (Cu), aluminum (Al), tungsten (W) titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), or ruthenium (Ru) or an alloy of the metal.

The height H1 of the heat conductive metal 250 in the vertical direction Z may be in the range of about or exactly 5 μm to about or exactly 25 μm. The height H1 may correspond to a height of the second wiring insulating layers 210. The heat conductive metal 250 may be separated from the second wiring 230.

The second semiconductor chip 400 may be mounted on an upper surface of the second wiring structure 200. The second semiconductor chip 400 may be mounted on the upper surface of the second wiring structure 200 through a first bump 450 in a flip chip manner.

The second semiconductor chip 400 may include a memory chip or a logic chip. In some example embodiments, the second semiconductor chip 400 may include a memory chip, and although not shown in the drawing, the second semiconductor chip 400 may be mounted on the second wiring structure 200 in a sealed state from a molding member. According to some example embodiments, the underfill layer 490 surrounding the first bump 450 may be disposed between the second semiconductor chip 400 and the second wiring structure 200. The underfill layer 490 may be formed of, for example, an epoxy resin formed by a capillary under-fill method. However, in some example embodiments, a molding material may directly fill the gap between the second semiconductor chip 400 and the second wiring structure 200 through a molded under-fill process. In this case, the underfill layer 490 may be omitted.

The first bump 450 may be disposed between the second semiconductor chip 400 and the second wiring structure 200. A plurality of first bumps 450 may be provided. As shown in FIG. 2, the plurality of first bumps 450 may be arranged to surround a first area A1. The first area A1 may be an area corresponding to the central portion of the underfill layer 490. The first bumps 450 may be disposed to surround the first area A1.

The first area A1 may be an area in which the first bumps 450 are not formed in the underfill layer 490. The first area A1 may be an area overlapping the central portion of the second semiconductor chip 400 in the underfill layer 490 in the vertical direction Z.

As the first bumps 450 are arranged to surround the first area A1, the first bumps 450 are not disposed in the first area A1, and an area of the second semiconductor chip 400 overlapping the first area A1 in the vertical direction Z may not contact the first bumps 450.

The heat conductive metal 250 may be formed in an area overlapping the first area A1 in the vertical direction Z in the second wiring structure 200. Therefore, the heat conductive metal 250 may not overlap the first bumps 450 in the vertical direction Z.

According to some example embodiments, a cross-sectional area of the first area A1 in an X-Y plane may not be greater than about 40 mm². A cross-sectional area in the X-Y plane of the heat conductive metal 250 formed in the area A1 overlapping the first area in the vertical direction Z in the second wiring structure 200 may also be not greater than about 40 mm².

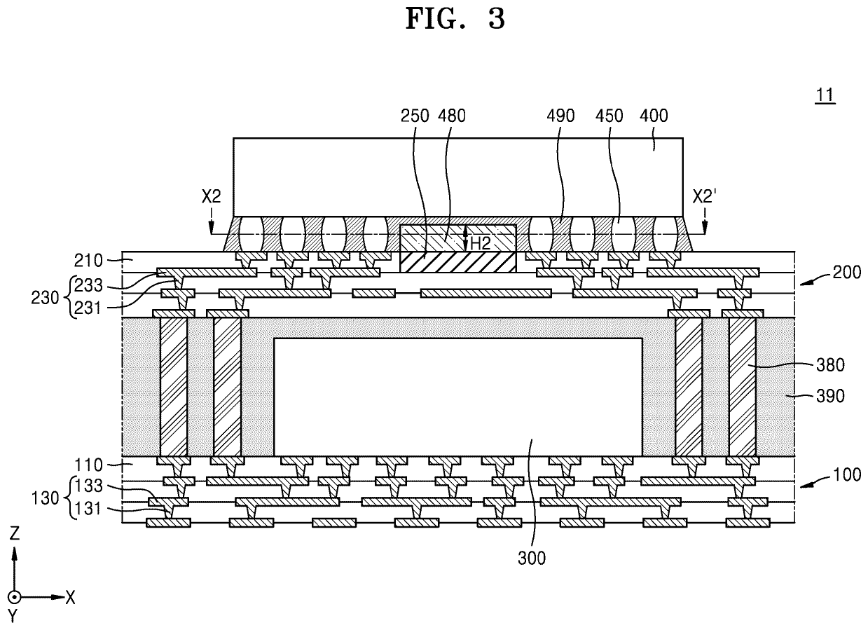

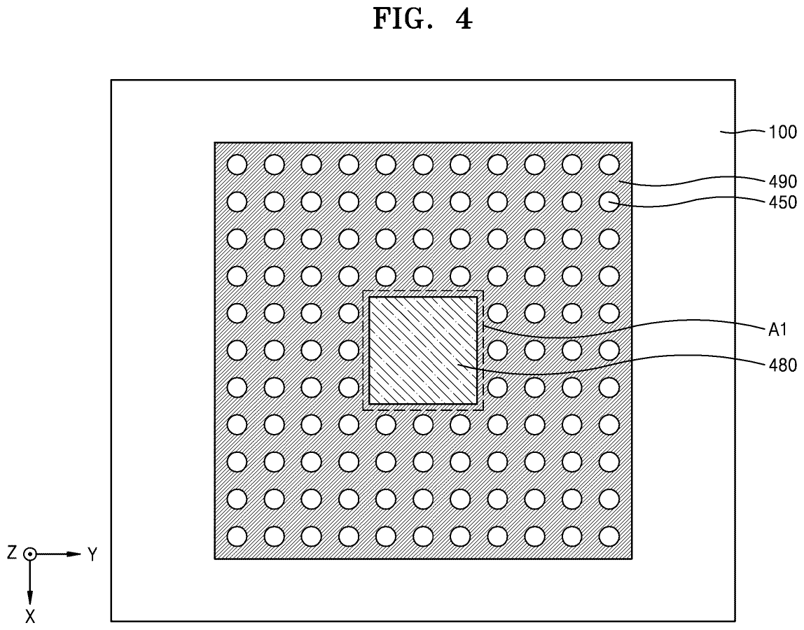

The semiconductor package 10 according to the disclosure may include the heat conductive metal 250 disposed below the first area A1, which is an area in which the first bumps 450 are not formed. The heat conductive metal 250 may have higher thermal conductivity than the molding member 390 and the second wiring insulating layer 210. The heat conductive metal 250 may provide a heat transfer path so that heat generated inside the semiconductor package 10 may be dissipated upward in the vertical direction Z. In addition, as is described below with reference to FIGS. 3 and 4, the heat conductive metal 250 may serve as an adhesive so that a first thermal interface material (TIM) 480 may be formed on the upper surface of the heat conductive metal 250 through a metal-to-metal direct connection. Conventionally, a separate adhesive may be disposed to form the first TIM 480. However, the separate adhesive has a problem in that the thermal conductivity is lower than that of metal and occupies a space where the first TIM 480 may be formed while being disposed on the underfill layer 490.

However, because the heat conductive metal 250 acting as an adhesive of the first TIM 480 is formed in the second wiring structure 200, the semiconductor package 10 according to the disclosure may not occupy space in the underfill layer 490, and thus, the height of the first TIM 480 in the vertical direction Z may be further increased. In addition, because the heat conductive metal 250 includes a metal having high thermal conductivity, heat generated inside the semiconductor package 10 may be more easily transferred to the first TIM 480.

FIG. 3 is a cross-sectional view illustrating a semiconductor package according to some example embodiments. FIG. 4 is a cross-sectional view of the semiconductor package of FIG. 3 taken along line X2-X2′. Hereinafter, among the descriptions of the semiconductor package 10 described with reference to FIGS. 1 and 2 and a semiconductor package 11 described with reference to FIG. 3, descriptions overlapping with each other are omitted, and differences between the semiconductor package 10 and the semiconductor package 11 are mainly described.

Referring to FIGS. 3 and 4, the semiconductor package 11 may include a first wiring structure 100, a first semiconductor chip 300, a second wiring structure 200, and a second semiconductor chip 400. The first wiring structure 100 may include a first wiring insulating layer 110 and a first wiring 130, and the second wiring structure 200 may include a second wiring insulating layer 210, a second wiring 230, and a heat conductive metal 250.

The second semiconductor chip 400 may be mounted in a flip chip method on the second wiring structure 200 through a first bump 450, and an underfill layer 490 surrounding the first bump 450 may be disposed between the second semiconductor chip 400 and the second wiring structure 200. A plurality of first bumps 450 may be provided and disposed to surround a first area A1 of the underfill layer 490.

A first TIM 480 may be formed on an upper surface of the heat conductive metal 250. The first TIM 480 may be formed in the first area A1 of the underfill layer 490. According to some example embodiments, the first TIM 480 may be formed through a metal-to-metal direct connection with the heat conductive metal 250. The metal-metal direct connection is a process of bonding another metal on a metal in a high-pressure and high-temperature environment, and may include, for example, a hybrid Kappa bonding process.

A cross-sectional area in the X-Y plane of the first TIM 480 may not be greater than about 40 mm². The first TIM 480 may have a height not greater than the height of the first bump 450 in a vertical direction Z. The first TIM 480 may have a height H2 of in the vertical direction Z not greater than about 150 μm.

According to some example embodiments, the first TIM 480 may include a metal having high thermal conductivity and may include the same metal as the heat conductive metal 250, but is not limited thereto. The first TIM 480 may include a metal different from the heat conductive metal 250.

The first TIM 480 may be formed in an idle space in the underfill layer 490 where the first bumps 450 are not formed, and because the first TIM 480 includes a metal having high thermal conductivity, heat generated inside the semiconductor package 11 may be efficiently discharged to the outside. In addition, because the first TIM 480 is formed using the heat conductive metal 250, a separate adhesive is not required, and the first TIM 480 may be freely formed within the underfill layer 490 without exceeding the height of the first bump 450 in the vertical direction Z.

In addition, heat generated inside the semiconductor package 11 may be efficiently discharged upwards in the vertical direction Z through the heat conductive metal 250 having high thermal conductivity and the first TIM 480.

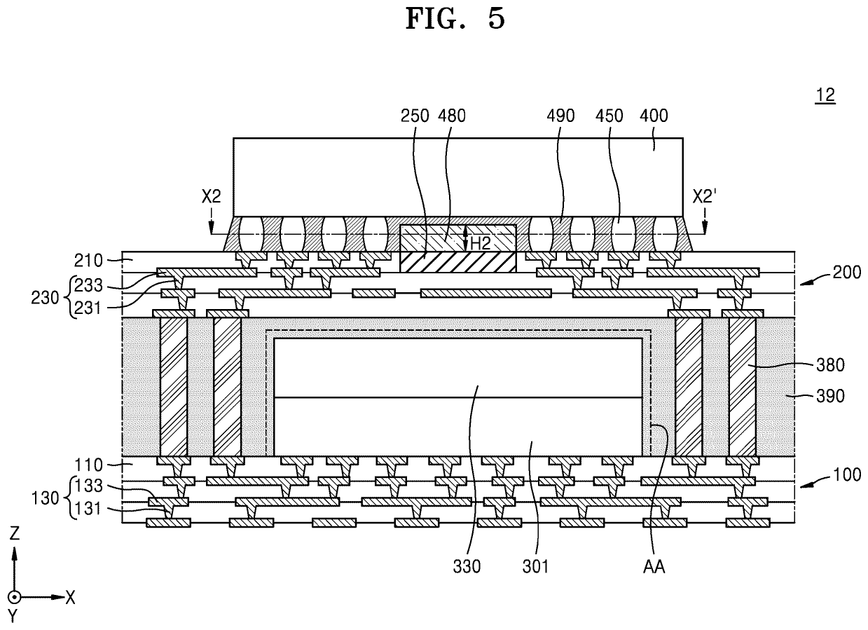

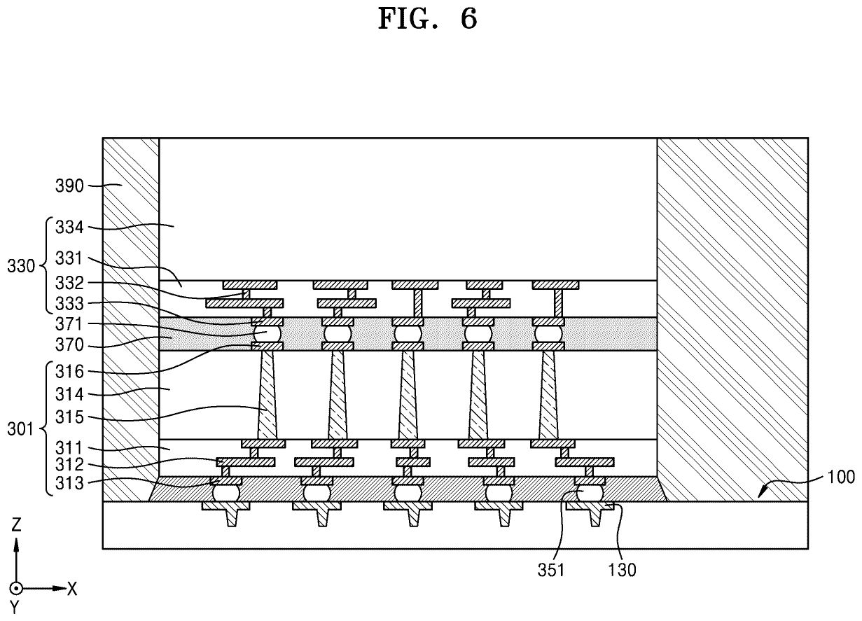

FIG. 5 is a cross-sectional view illustrating a semiconductor package according to some example embodiments FIG. 6 is an enlarged view of portion AA of the semiconductor package of FIG. 5. Hereinafter, among the descriptions of the semiconductor package 11 described with reference to FIGS. 3 and 4 and a semiconductor package 12 described with reference to FIG. 5, descriptions overlapping with each other are omitted, and differences between the semiconductor package 11 and the semiconductor package 12 are mainly described.

Referring to FIGS. 5 and 6, the semiconductor package 12 may include a first wiring structure 100, a first semiconductor chip 301, a second wiring structure 200, a second semiconductor chip 400, and a third semiconductor chip 330. The first wiring structure 100 may include a first wiring insulating layer 110 and a first wiring 130, and the second wiring structure 200 may include a second wiring insulating layer 210, a second wiring 230, and a heat conductive metal 250.

The first semiconductor chip 301 may be disposed on the upper surface of the first wiring structure 100. The third semiconductor chip 330 may be stacked on the first semiconductor chip 301. The third semiconductor chip 330 may be disposed on the upper surface of the first semiconductor chip 301. According to some example embodiments, the first semiconductor chip 301 and the third semiconductor chip 330 may be disposed on the upper surface of the first wiring structure 100. According to some example embodiments, each of the first semiconductor chip 301 and the third semiconductor chip 330 may be a logic chip or a memory chip. For example, both the first semiconductor chip 301 and the third semiconductor chip 330 may be memory chips of the same type, or one of the first semiconductor chip 301 and the third semiconductor chip 330 may be a memory chip and the other may be a logic chip.

The first semiconductor chip 301 may include a first semiconductor substrate 314, a first pattern layer 311, first bump pads 313, and second bump pads 316.

The first semiconductor substrate 314 may have upper surface and lower surface that are opposite to each other. The upper surface may face the third semiconductor chip 330 and the lower surface may face the first wiring structure 100. The upper surface may be referred to as an inactive surface, and the lower surface may be referred to as an active surface.

The first semiconductor substrate 314 may include silicon (Si), for example, crystalline silicon, polycrystalline silicon, or amorphous silicon. Alternatively, the first semiconductor substrate 314 may include a semiconductor element such as germanium (Ge) or a compound semiconductor such as silicon carbide (SiC), gallium arsenide (GaAs), indium arsenide (InAs), and indium phosphide (InP). Meanwhile, the first semiconductor substrate 314 may have a silicon on insulator (SOI) structure. For example, the first semiconductor substrate 314 may include a buried oxide layer (BOX layer). The first semiconductor substrate 314 may include a conductive region, for example, a well doped with impurities or a structure doped with impurities. In addition, the first semiconductor substrate 314 may have various device isolation structures such as a shallow trench isolation (STI) structure.

The first pattern layer 311 may include a first pattern 312 electrically connected to a plurality of semiconductor elements formed on the first semiconductor substrate 314. The first pattern 312 may include a metal wiring layer and a via plug. For example, the first pattern 312 may have a multilayer structure in which two or more metal wiring layers or two or more via plugs are alternately stacked.

According to some example embodiments, the first pattern layer 311 may be formed on the lower surface, which is the active surface of the first semiconductor substrate 314. The first pattern layer 311 may be positioned under the first semiconductor substrate 314. The first semiconductor chip 301 may include a through electrode 315 penetrating at least a portion of the first pattern layer 311 and the first semiconductor substrate 314.

The first bump pad 313 may be disposed on the lower surface of the first pattern layer 311 and may be electrically connected to the first pattern 312 inside the first pattern layer 311. The first bump pad 313 may be electrically connected to the through electrode 315 through the first pattern 312.

The through electrode 315 may pass through the first semiconductor substrate 314 and portion of the first pattern layer 311. The through electrode 315 may extend in a vertical direction Z from the first pattern layer 311 toward the upper surface of the first semiconductor substrate 314 and may be electrically connected to the first pattern 312 provided in the first pattern layer 311. Accordingly, the first bump pad 313 may be electrically connected to the through electrode 315 through the first pattern 312. The through electrode 315 may have a tapered shape in which a width in a horizontal direction decreases or increases as a level in the vertical direction increases. At least a portion of the through electrode 315 may have a pillar shape. The through electrode 315 may be a through silicon via (TSV).

The second bump pad 316 may be formed on an upper surface of the first semiconductor substrate 314, that is, on an inactive surface of the first semiconductor substrate 314. The second bump pad 316 may be made of substantially the same or the same material as the first bump pad 313. In addition, although not shown, according to some example embodiments, a passivation layer may be formed on the upper surface of the first semiconductor substrate 314 to surround a portion of the side surface of the second bump pad 316.

A second bump 351 may be disposed to contact the first bump pad 313. The second bump 351 may be disposed to contact the first wiring 130 disposed on the first wiring structure 100. The second bump 351 may electrically connect the first semiconductor chip 301 to the first wiring structure 100. The first semiconductor chip 301 may receive at least one of a control signal, a power signal, and a ground signal for operation of the first semiconductor chip 301 from the outside through the second bump 351, may receive a data signal to be stored in the first semiconductor chip 301 from the outside, or may provide data stored in the first semiconductor chip 301 to the outside. For example, the second bump 351 may have a pillar structure, a ball structure, or a solder layer.

The third semiconductor chip 330 may include a second semiconductor substrate 334, a second pattern layer 331, and third bump pads 333. Because the third semiconductor chip 330 may have the same or similar characteristics as the first semiconductor chip 301, differences from the first semiconductor chip 301 are mainly described.

The second semiconductor substrate 334 may have lower and upper surfaces that are opposite to each other. The lower surface may face the first semiconductor chip 301, and the upper surface may be a surface opposite to the lower surface. The upper surface may be referred to as an inactive surface, and the lower surface may be referred to as an active surface.

The second pattern layer 331 may include a second pattern 332 electrically connected to a plurality of semiconductor elements formed on the second semiconductor substrate 334. The second pattern 332 may include a metal wiring layer and a via plug. For example, the second pattern 332 may have a multilayer structure in which two or more metal wiring layers or two or more via plugs are alternately stacked.

According to some example embodiments, the second pattern layer 331 may be formed on the lower surface of the second semiconductor substrate 334, which is an active surface. The second pattern layer 331 may be positioned under the second semiconductor substrate 334. The second semiconductor substrate 334 may be spaced apart from the first semiconductor chip 301 in the vertical direction Z with the second pattern layer 331 interposed therebetween.

A third bump pad 333 may be disposed on the lower surface of the second pattern layer 331 and may be electrically connected to the second pattern 332 inside the second pattern layer 331. The adhesive layer 370 may be positioned between the first semiconductor chip 301 and the third semiconductor chip 330. The adhesive layer 370 may be formed to surround a third bump 371.

The third bump 371 may be disposed to contact the second bump pad 316 and the third bump pad 333. The third bump 371 may electrically connect the first semiconductor chip 301 to the third semiconductor chip 330. The third semiconductor chip 330 may be electrically connected to the first semiconductor chip 301 through the third bump 371 between the first semiconductor chip 301 and the third semiconductor chip 330. The third semiconductor chip 330 may receive at least one of a control signal, a power signal, and a ground signal for operation of the third semiconductor chip 330, receive a data signal to be stored in the third semiconductor chip 330, or provide data stored in the third semiconductor chip 330 to the outside, through the third bump 371. The semiconductor package 12 according to some example embodiments may include a 3D-IC structure in which the third semiconductor chip 330 is mounted on the first semiconductor chip 301 as described above.

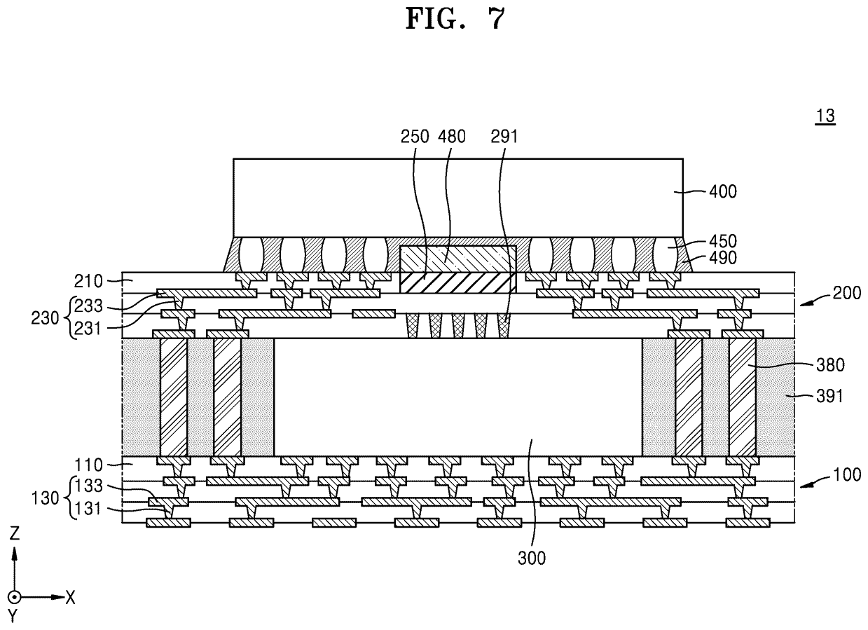

FIG. 7 is a cross-sectional view illustrating a semiconductor package according to some example embodiments. Hereinafter, among the descriptions of the semiconductor package 11 described with reference to FIGS. 3 and 4 and a semiconductor package 13 described with reference to FIG. 7, descriptions overlapping with each other are omitted, and differences between the semiconductor package 11 and the semiconductor package 13 are mainly described.

Referring to FIG. 7, the semiconductor package 13 may include a first wiring structure 100, a first semiconductor chip 300, a second wiring structure 200, and a second semiconductor chip 400. The first wiring structure 100 may include a first wiring insulating layer 110 and a first wiring 130, and the second wiring structure 200 may include a second wiring insulating layer 210, a second wiring 230, a heat conductive metal 250, and a heat conductive via pattern 291.

A molding member 391 may surround the first semiconductor chip 300. According to some example embodiments, an upper surface of the molding member 391 may be on the same plane as an upper surface of the first semiconductor chip 300. That is, the upper surface of the molding member 391 may have the same level in the vertical direction Z as the upper surface of the first semiconductor chip 300. An upper surface of the conductive pillar 380 may be on the same plane as an upper surface of the first semiconductor chip 300. Accordingly, the upper surface of the conductive pillar 380, the upper surface of the first semiconductor chip 300, and the upper surface of the molding member 391 may all be on the same plane.

As the upper surface of the molding member 391 is on a same plane with an upper surface of the first semiconductor chip 300, the upper surface of the first semiconductor chip 300 may contact the lower surface of the second wiring structure 200.

The heat conductive via pattern 291 may be formed in the second wiring structure 200 and may be formed to contact the upper surface of the first semiconductor chip 300. However, the heat conductive via pattern 291 is not limited thereto, and the heat conductive via pattern 291 may be formed near the upper surface of the first semiconductor chip 300.

According to some example embodiments, the heat conductive via pattern 291 may include the same metal as the second wiring 230. However, the heat conductive via pattern 291 is not limited thereto, and the heat conductive via pattern 291 may include a metal different from that of the second wiring 230.

The heat conductive via pattern 291 may have a shape extending in the vertical direction Z. According to some example embodiments, the heat conductive via pattern 291 may have a tapered shape in which a horizontal width increases from a lower side to an upper side. According to some example embodiments, the heat conductive via pattern 291 may be formed simultaneously with or in sequency with the second wiring via 231.

The heat conductive via pattern 291 may be formed adjacent to the upper surface of the first semiconductor chip 300 and may include a metal having high thermal conductivity. Accordingly, heat generated in the first semiconductor chip 300 may be transferred to the heat conductive metal 250 and the first TIM 480 through the heat conductive via pattern 291. As a result, heat generated inside the semiconductor package 13 may be easily discharged to the outside through the heat conductive via pattern 291, the heat conductive metal 250, and the first TIM 480.

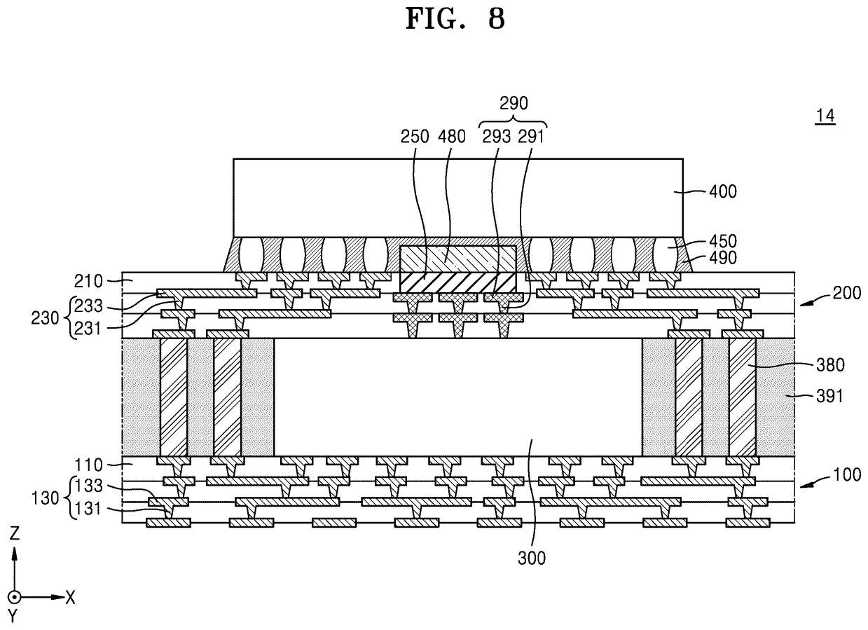

FIG. 8 is a cross-sectional view illustrating a semiconductor package according to some example embodiments. Hereinafter, among the descriptions of the semiconductor package 13 described with reference to FIG. 7 and a semiconductor package 14 described with reference to FIG. 8, descriptions overlapping with each other are omitted, and differences between the semiconductor package 13 and the semiconductor package 14 are mainly described.

The semiconductor package 14 may include a first wiring structure 100, a first semiconductor chip 300, a second wiring structure 200, and a second semiconductor chip 400. The first wiring structure 100 may include a first wiring insulating layer 110 and a first wiring 130, and the second wiring structure 200 may include a second wiring insulating layer 210, a second wiring 230, a heat conductive metal 250, and a heat conductive pattern 290. The heat conductive pattern 290 may include a heat conductive via pattern 291 and a heat conductive line pattern 293.

The molding member 391 may surround the first semiconductor chip 300. According to some example embodiments, an upper surface of the molding member 391 may be on the same plane as an upper surface of the first semiconductor chip 300.

The heat conductive via pattern 291 may be formed in the second wiring structure 200 and may be formed to contact the upper surface of the first semiconductor chip 300. However, heat conductive via pattern 291 is not limited thereto, and the heat conductive via pattern 291 may be formed near the upper surface of the first semiconductor chip 300.

The heat conductive via pattern 291 may be provided in the second wiring insulating layer 210. According to some example embodiments, the heat conductive via pattern 291 may be provided on each of at least two or more second wiring insulating layers 210 among a plurality of second wiring insulating layers 210.

The heat conductive line pattern 293 is provided in the second wiring insulating layer 210 and may have a shape extending in a horizontal direction. In some example embodiments, the heat conductive line pattern 293 may be provided on each of the plurality of second wiring insulating layers 210. The heat conductive line pattern 293 may be provided on upper surfaces of each of the heat conductive via patterns 291 provided on different layers. The heat conductive line pattern 293 may include a metal having high thermal conductivity, for example, a higher thermal conductively compared to the materials surrounding and/or adjacent to the heat conductive line pattern 293.

The heat conductive line pattern 293 may connect heat conductive via patterns 291 provided on different layers to each other.

According to some example embodiments, among the plurality of heat conductive line patterns 293, an uppermost heat conductive line pattern 293 may contact the lower surface of the heat conductive metal 250.

The heat conductive pattern 290 may provide a path for heat to move from the upper surface of the first semiconductor chip 300 to the lower surface of the heat conductive metal 250. Accordingly, heat generated inside the semiconductor package 14 may be transferred to the heat conductive metal 250 and the first TIM 480 through the heat conductive pattern 290, and heat passing through the first TIM 480 may be emitted to the outside through the underfill layer 490 and the second semiconductor chip 400.

In addition, when the uppermost heat conductive line pattern 293 contacts the lower surface of the heat conductive metal 250, the heat conductive pattern 290 may transfer heat to the heat conductive metal 250 through conduction, and thus heat generated inside the semiconductor package 14 may be more easily discharged to the outside.

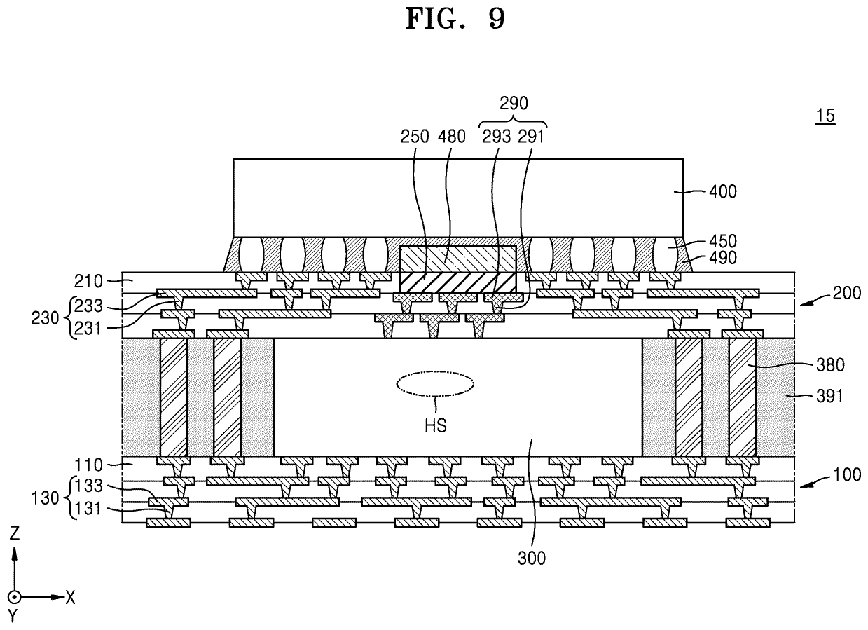

FIG. 9 is a cross-sectional view illustrating a semiconductor package according to some example embodiments. Hereinafter, among the descriptions of the semiconductor package 14 described with reference to FIG. 8 and a semiconductor package 15 described with reference to FIG. 9, descriptions overlapping with each other are omitted, and differences between the semiconductor package 14 and the semiconductor package 15 are mainly described.

The semiconductor package 15 may include a first wiring structure 100, a first semiconductor chip 300, a second wiring structure 200, and a second semiconductor chip 400. The first wiring structure 100 may include a first wiring insulating layer 110 and a first wiring 130, and the second wiring structure 200 may include a second wiring insulating layer 210, a second wiring 230, a heat conductive metal 250, and a heat conductive pattern 290. The thermal conductive pattern 290 may include a heat conductive via pattern 291 and a heat conductive line pattern 293.

A heat source area HS may be formed inside the first semiconductor chip 300. The heat source area HS may be an area generating more heat than a peripheral area inside the first semiconductor chip 300. According to some example embodiments, the heat source area HS may not overlap or partially overlap the first area A1 in the vertical direction Z. That is, the heat source area HS and the first area A1 may face each other in a diagonal direction on the X-Z plane.

The heat conductive pattern 290 may provide a path through which heat generated in the heat source area HS is transferred to the heat conductive metal 250. Among the heat conductive via patterns 291, the heat conductive via pattern 291 positioned at the lowermost level may be disposed to overlap the heat source area HS in the vertical direction Z. In addition, among the heat conductive line patterns 293, an uppermost heat conductive line pattern 293 may contact the lower surface of the heat conductive metal 250. Accordingly, heat generated from the heat source area HS may be more efficiently transferred to the heat conductive metal 250 through the heat conductive pattern 290.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While the disclosure has been particularly shown and described with reference to some example embodiments thereof, it will be understood that various changes in form and details may be made therein without departing from the spirit and scope of the following claims.

What is claimed is:

1. A semiconductor package comprising:
a first wiring structure including a first wiring configured to transmit electrical signals;
a first semiconductor chip on the first wiring structure;
a molding member surrounding the first semiconductor chip;
a second wiring structure including a second wiring and a heat conductive metal, the second wiring structure on an upper surface of the molding member, the second wiring configured to transmit an electrical signal, and the heat conductive metal not electrically connected to the second wiring;
a second semiconductor chip on an upper surface of the second wiring structure;
a plurality of first bumps between the second wiring structure and the second semiconductor chip and electrically connecting the second wiring to the second semiconductor chip;
an underfill layer covering the plurality of first bumps; and
a first thermal interface material (TIM) formed on an upper surface of the heat conductive metal,
the upper surface of the heat conductive metal exposed in a vertical direction from the second wiring structure, and
the heat conductive metal not overlapping the plurality of first bumps in the vertical direction.

2. The semiconductor package of claim 1, wherein the plurality of first bumps surround a first area corresponding to a central portion of the underfill layer.

3. The semiconductor package of claim 1, wherein the upper surface of the molding member is on a same plane with an upper surface of the second semiconductor chip.

4. The semiconductor package of claim 3, further comprising a heat conductive via pattern contacting the upper surface of the first semiconductor chip and extending in the vertical direction.

5. The semiconductor package of claim 4, wherein
the second wiring structure includes a plurality of second wiring insulation layers stacked in a vertical direction,
the heat conductive via pattern is on each of at least two or more second wiring insulating layers among a plurality of second wiring insulating layers,
a heat conductive line pattern extending in a horizontal direction on an upper surface of each of the heat conductive via patterns on different layers, and
among the heat conductive line patterns, an uppermost heat conductive line pattern in the vertical direction is in contact with a lower surface of the heat conductive metal.

6. The semiconductor package of claim 5, wherein
the first semiconductor chip includes a heat source area configured to generate more heat than a peripheral area,
among the heat conductive via patterns, the heat conductive via pattern at the lowest level in the vertical direction overlaps the heat source area in the vertical direction.

7. The semiconductor package of claim 1, further comprising a third semiconductor chip stacked on top of the first semiconductor chip.

8. The semiconductor package of claim 1, wherein
the second wiring structure includes a plurality of second wiring insulation layers stacked in a vertical direction, and
each of the plurality of second wiring insulating layers includes at least one of photo imageable dielectric (PID) and photosensitive polyimide.

9. The semiconductor package of claim 1, wherein a cross-sectional area in an X-Y plane of the heat conductive metal is not greater than 40 mm².

10. The semiconductor package of claim 1, wherein a vertical height of the heat conductive metal is in a range of 5 μm to 25 μm, and a vertical height of the first TIM is not greater than 150 μm.

11. The semiconductor package of claim 1, further comprising
a conductive pillar vertically penetrating the molding member and electrically connecting the first wiring to the second wiring; and
an external connection bump on a lower surface of the first wiring structure and electrically connecting the first wiring structure to an external device.

12. A semiconductor package comprising:
a first wiring structure including a first wiring configured to transmit electrical signals;
a first semiconductor chip on the first wiring structure;
a molding member surrounding the first semiconductor chip;
a second wiring structure including a second wire configured to transmit an electrical signal, a heat conductive metal not electrically connected to the second wire, and a heat conductive via pattern contacting an upper surface of the first semiconductor chip and extending in a vertical direction, the second wiring structure on an upper surface of the molding member;
a second semiconductor chip on an upper surface of the second wiring structure;
a plurality of first bumps between the second wiring structure and the second semiconductor chip and electrically connecting the second wiring to the second semiconductor chip;
an underfill layer covering the plurality of first bumps; and
a first TIM on an upper surface of the heat conductive metal,
the upper surface of the heat conductive metal exposed in a vertical direction from the second wiring structure,
the upper surface of the molding member on a same plane with an upper surface of the second semiconductor chip, and
the heat conductive metal not overlapping the plurality of first bumps in the vertical direction.

13. The semiconductor package of claim 12, wherein
the second wiring structure includes a plurality of second wiring insulation layers stacked in a vertical direction, and
each of the plurality of second wiring insulating layers includes at least one of PID and photosensitive polyimide.

14. The semiconductor package of claim 13, wherein
the heat conductive via pattern is on each of at least two or more second wiring insulating layers among a plurality of second wiring insulating layers,
a heat conductive line pattern extending in a horizontal direction is on an upper surface of each of the heat conductive via patterns provided on different layers, and
among the heat conductive line patterns, an uppermost heat conductive line pattern in the vertical direction is in contact with a lower surface of the heat conductive metal.

15. The semiconductor package of claim 12, wherein
a third semiconductor chip is stacked on top of the first semiconductor chip,
the first semiconductor chip includes a first semiconductor substrate and a pattern layer, and
the pattern layer of the first semiconductor chip faces the second wiring structure.

16. The semiconductor package of claim 12, wherein
the plurality of first bumps surround a first area corresponding to a central portion of the underfill layer,
the first TIM is in the first area, and
a cross-sectional area in an X-Y plane of the first TIM is not greater than about 40 mm².

17. The semiconductor package of claim 16, wherein a vertical height of the heat conductive metal is in a range of 5 μm to 25 μm, and a vertical height of the first TIM does not exceed 150 μm.

18. A semiconductor package comprising:
a first wiring structure including a first wiring configured to transmit an electrical signal, and a first wiring insulating layer covering the first wiring;
a first semiconductor chip on the first wiring structure;
a molding member surrounding the first semiconductor chip;
a second wiring structure including a second wire configured to transmit an electrical signal, a heat conductive metal not electrically connected to the second wire, a heat conductive via pattern contacting an upper surface of the first semiconductor chip and extending in a vertical direction, and a second wire insulating layer covering the second wire, the heat conductive metal, and the heat conductive via pattern, the second wiring structure on an upper surface of the molding member;
a conductive pillar vertically penetrating the molding member and electrically connecting the first wiring to the second wire;
a second semiconductor chip on an upper surface of the second wiring structure;
a plurality of first bumps between the second wiring structure and the second semiconductor chip and electrically connecting the second wiring to the second semiconductor chip;
an underfill layer covering the plurality of first bumps; and
a first TIM formed on an upper surface of the heat conductive metal;
the plurality of first bumps surround a first area corresponding to a central portion of the underfill layer,
the upper surface of the heat conductive metal exposed in a vertical direction from the second wiring structure,
the upper surface of the molding member on a same plane with an upper surface of the second semiconductor chip,
the second wiring insulating layer includes at least one of PID and photosensitive polyimide, and
the heat conductive metal not overlapping the plurality of first bumps in the vertical direction.

19. The semiconductor package of claim 18, wherein
a cross-sectional area in an X-Y plane of the first TIM is not greater than 40 mm², and a height in the vertical direction is not greater than 150 μm, and
a vertical height of the heat conductive metal is in a range of 5 μm to 25 μm.

20. The semiconductor package of claim 18, wherein
a third semiconductor chip is stacked on top of the first semiconductor chip,
the first semiconductor chip includes a first semiconductor substrate and a pattern layer, and
the pattern layer of the first semiconductor chip faces the second wiring structure.
